(19) United States
(12) Patent Application Publication
(10) Pub. No.: US 2014/0299912 A1
(43) Pub. Date: Oct. 9, 2014

(54) SILICON-CONTROLLED-RECTIFIER WITH ADJUSTABLE HOLDING VOLTAGE

(71) Applicant: Amazing Microelectronic Corp., New Taipei City (TW)

(72) Inventors: Kun-Hsien LIN, Hsinchu City (TW); Che-Hao CHUANG, Hsinchu County (TW); Ryan Hsin-Chin JIANG, Taipei City (TW)

(21) Appl. No.: 14/309,660

(22) Filed: Jun. 19, 2014

Related U.S. Application Data
(63) Continuation-in-part of application No. 13/331,241, filed on Dec. 20, 2011.

(51) Int. Cl. H01L 29/74

(52) U.S. Cl. CPC H01L 29/7424
USPC 257/119

(57) ABSTRACT

In a silicon-controlled-rectifier (SCR) with adjustable holding voltage, an epitaxial layer is formed on a heavily doped semiconductor layer. A first N-well having a first P-heavily doped area is formed in the epitaxial layer. A first P-well is formed in the epitaxial layer. Besides, a first N-heavily doped area is formed in the first P-well. At least one deep isolation trench is formed in the epitaxial layer, having a depth greater than the depth of the first N-type well and located between the first P-heavily doped area and the first N-heavily doped area. A distance between the deep isolation trench and the heavily doped semiconductor layer is larger than zero.

### CROSS REFERENCE TO RELATED APPLICATIONS

This application is a Continuation-in-Part of co-pending application Ser. No. 13/331,241, filed on Dec. 20, 2011, for which priority is claimed under 35 U.S.C. §120 and the entire contents of all of which are hereby incorporated by reference.

### BACKGROUND OF THE INVENTION

1. Field of the Invention

The present invention relates to a silicon-controlled-rectifier (SCR), particularly to a SCR with adjustable holding voltage.

2. Description of the Related Art

The electrostatic discharge (ESD) attacking has become a serious problem with the continuous narrowing of transistors in the integrated circuits. The SCR (Silicon-Controlled Rectifier) device formed by the parasitic pnp and npn bipolar transistors has been commonly used for ESD protection. Due to the low holding voltage (˜1V), the SCR device can sustain much higher ESD voltage within smaller layout area, as comparing to the other ESD protection devices (such as diode, MOS, BJT, or field-oxide device). However, because the holding voltage of the SCR device is smaller than the supply voltage (for example, supply voltage of 3.3V), the SCR device is susceptible to latch-up issue during normal circuit operating condition. The SCR device may be accidentally triggered on by the external noise pulses while the IC is in the normal operating condition. The latch-up phenomena often leads to IC function failure or even destruction.

The U.S. Pat. No. 6,605,493 discloses the holding voltage of SCR device is only ˜1V, which is smaller than the power supply voltage. Therefore, the SCR device with such designs is susceptible to latch-up issue during normal circuit operating condition. In order to solve the latch-up issue, the holding voltage of SCR device should be increased to be higher than the supply voltage, as shown in FIG. 1. In the US patents NO. 20040100745 and U.S. Pat. No. 6,433,368, the extra circuit is applied on the SCR device to increase the holding voltage. However, such designs are complicated and the holding voltage can be adjusted with only a small range.

To overcome the abovementioned problems, the present invention provides a SCR with adjustable holding voltage, so as to solve the afore-mentioned problems of the prior art.

### SUMMARY OF THE INVENTION

A primary objective of the present invention is to provide a silicon-controlled-rectifier (SCR), which changes the number of the deep isolation trench and the distance between the deep isolation trench and the heavily doped semiconductor layer to adjust the holding voltage to avoid the latch-up issue. With this simple design, the holding voltage can be adjusted with a large range. To achieve the abovementioned objectives, the present invention provides a SCR with adjustable holding voltage, which comprises a heavily doped semiconductor layer and an epitaxial layer formed on the heavily doped semiconductor layer. A first N-type well having a first P-type heavily doped area is formed in the epitaxial layer. A first P-type well is formed in the epitaxial layer. Besides, a first N-type heavily doped area is formed in the first P-type well. At least one deep isolation trench is formed in the epitaxial layer and located between the first P-type heavily doped area and the first N-type heavily doped area, wherein a distance between the deep isolation trench and the heavily doped semiconductor layer is larger than zero. The depth of the deep isolation trench is greater than the depth of the first N-type well.

Below, the embodiments are described in detail in cooperation with the drawings to make easily understood the technical contents, characteristics and accomplishments of the present invention.

### BRIEF DESCRIPTION OF THE DRAWINGS

FIG. 1 is a diagram showing an I-V characteristic curve of a silicon-controlled-rectifier (SCR) device according to the prior art;

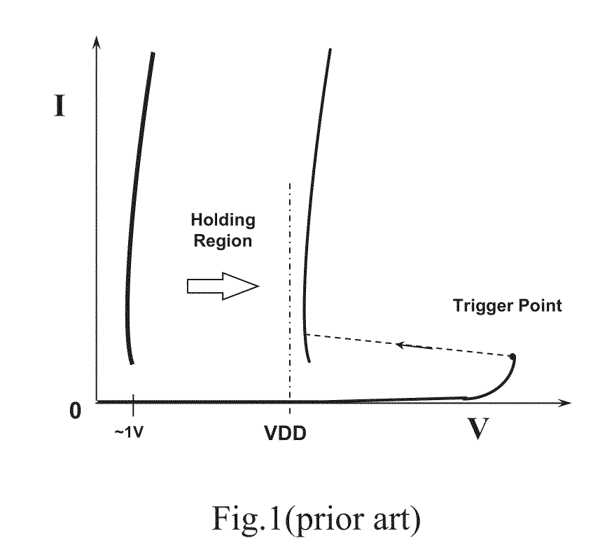

FIG. 2 is a sectional view schematically showing a SCR according to the first embodiment of the present invention;

FIG. 3 is a diagram showing an I-V characteristic curve of a SCR according to an embodiment of the present invention;

FIG. 4 is a sectional view schematically showing a SCR according to the second embodiment of the present invention;

FIG. 5 is a sectional view schematically showing a SCR according to the third embodiment of the present invention; and

FIG. 6 is a sectional view schematically showing a SCR according to the fourth embodiment of the present invention.

### DETAILED DESCRIPTION OF THE INVENTION

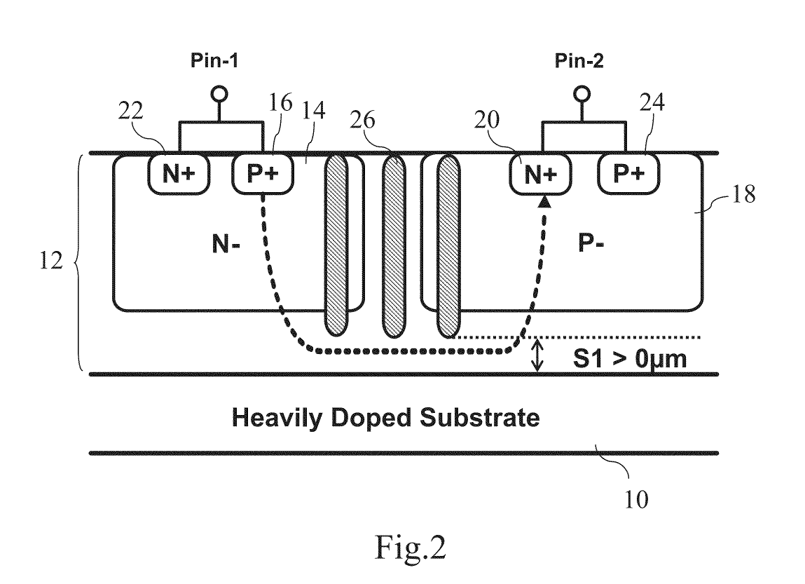

Refer to FIG. 2. The first embodiment of the present invention comprises a heavily doped semiconductor substrate 10 used as a heavily doped semiconductor layer, wherein the heavily doped semiconductor substrate 10 is an N-type heavily doped substrate or a P-type heavily doped substrate. An epitaxial layer 12 is formed on the heavily doped semiconductor substrate 10. A first N-type well 14 is formed in the epitaxial layer 12, and a first P-type heavily doped area 16 is formed in the first N-type well 14. The first N-type well 14 is exemplified by a lightly doped N-type well. A first P-type well 18 is formed in the epitaxial layer 12, and a first N-type heavily doped area 20 is formed in the first P-type well 18. The first P-type well 18 is exemplified by a lightly doped P-type well. Besides, a second N-type heavily doped area 22 is formed in the first N-type well 14, and the first P-type heavily doped area 16 and the second N-type heavily doped area 22 are coupled to the first pin. A second P-type heavily doped area 24 is formed in the first P-type well 18, and the first N-type heavily doped area 20 and the second P-type heavily doped area 24 are coupled to the second pin. At least one deep isolation trench 26 is formed in the epitaxial layer 12. The deep isolation trench 26 is located between the first P-type heavily doped area 16 and the first N-type heavily doped area 20. The depth of the deep isolation trench 26 is greater than the depths of the first N-type well 14 and the first P-type well 18. There is the spacing S1 defined as a distance between the deep isolation trench 26 and the heavily doped semiconductor substrate 10, wherein the spacing S1 is larger than zero. In addition, the spacing S1 is less than the distance between the heavily doped semiconductor substrate 10 and the first N-type well 14. The spacing S1 is less than the distance between the heavily doped semiconductor substrate 10 and the first P-type well 18.

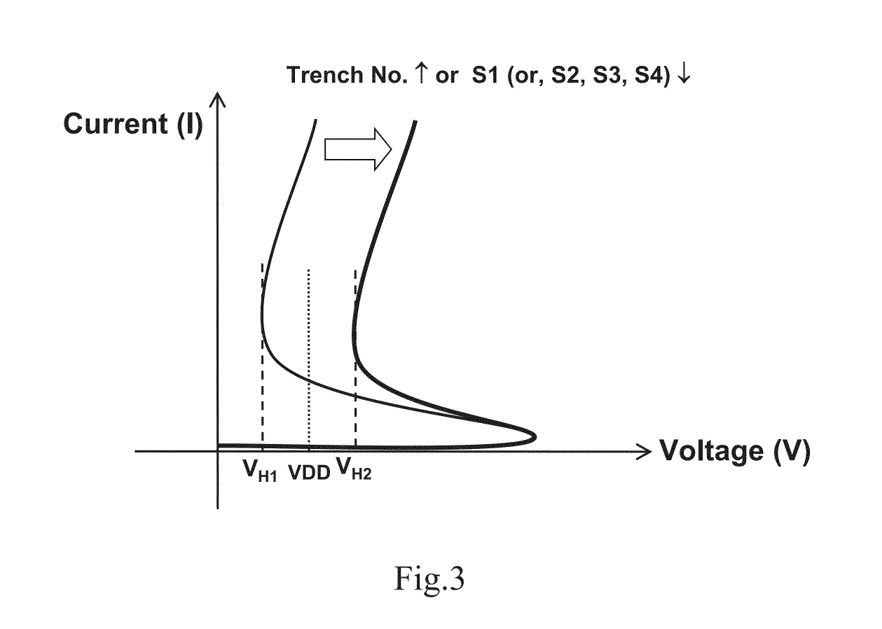

When the first P-type heavily doped area 16 receives the positive ESD pulse while the first N-type heavily doped area 20 is grounded, the electrostatic discharge (ESD) current flows from the first P-type heavily doped area 16 to the first N-type heavily doped area 20 through the first N-type well 14 and the first P-type well 18. The deep isolation trench 26 can reduce the current gain of parasitic pnp and npn bipolar transistors of SCR device, thus the holding voltage can be increased. As a result, the more the number of the deep isolation trench 26 is, the higher the holding voltage is. Additionally, the decrease of spacing S1 can reduce the current gain of parasitic pnp and npn bipolar transistors of SCR device, thus the holding voltage can be increased. As a result, the shorter the spacing S1 is, the higher the holding voltage is. As shown in FIG. 3, the original holding voltage V_{H1} of the first embodiment is adjusted to V_{H2} larger than power supply V_{DD} after increasing the number of the deep isolation trench 26 or decreasing the spacing S1. In other words, the first embodiment has simple design to adjust the holding voltage with a large range, thereby avoiding the latch-up issue.

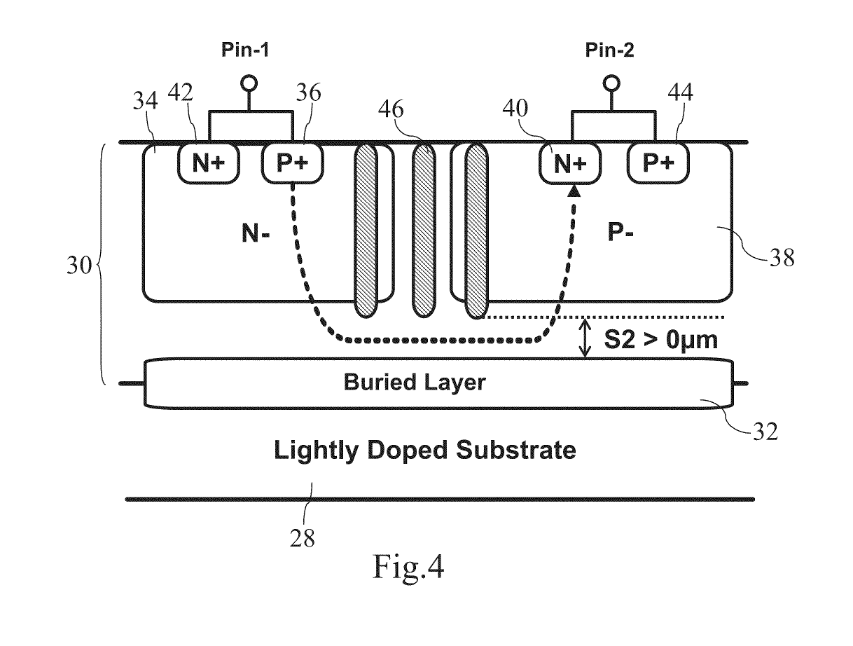

Refer to FIG. 4. The second embodiment of the present invention comprises a lightly doped semiconductor substrate 28, such as an N-type lightly doped substrate or a P-type lightly doped substrate. An epitaxial layer 30 is formed on the lightly doped semiconductor substrate 28. A heavily doped buried layer 32, such as an N-type heavily doped buried layer or a P-type heavily doped buried layer, used as a heavily doped semiconductor layer is formed in the epitaxial layer 30 and the lightly doped semiconductor substrate 28, whereby a part of the epitaxial layer 30 is formed on the heavily doped buried layer 32. A first N-type well 34 is formed in the epitaxial layer 30, and a first P-type heavily doped area 36 is formed in the first N-type well 34. The first N-type well 34 is exemplified by a lightly doped N-type well. A first P-type well 38 is formed in the epitaxial layer 30, and a first N-type heavily doped area 40 is formed in the first P-type well 38. The first P-type well 38 is exemplified by a lightly doped P-type well. The first N-type well 34 and the first P-type well 38 are located above the heavily doped buried layer 32. Besides, a second N-type heavily doped area 42 is formed in the first N-type well 34, and the first P-type heavily doped area 36 and the second N-type heavily doped area 42 are coupled to the first pin. A second P-type heavily doped area 44 is formed in the first P-type well 38, and the first N-type heavily doped area 40 and the second P-type heavily doped area 44 are coupled to the second pin. At least one deep isolation trench 46 is formed in the epitaxial layer 30. The deep isolation trench 46 is located between the first P-type heavily doped area 36 and the first N-type heavily doped area 40. The depth of the deep isolation trench 46 is greater than the depths of the first N-type well 34 and the first P-type well 38. There is the spacing S2 defined as a distance between the deep isolation trench 46 and the heavily doped buried layer 32, wherein the spacing S2 is larger than zero. In addition, the spacing S2 is less than the distance between the heavily doped buried layer 32 and the first N-type well 34. The spacing S2 is less than the distance between the heavily doped buried layer 32 and the first P-type well 38.

When the first P-type heavily doped area 36 receives the positive ESD pulse while the first N-type heavily doped area 40 is grounded, the ESD current flows from the first P-type heavily doped area 36 to the first N-type heavily doped area 40 through the first N-type well 34 and the first P-type well 38. The deep isolation trench 46 can reduce the current gain of parasitic pnp and npn bipolar transistors of SCR device, thus the holding voltage can be increased. As a result, the more the number of the deep isolation trench 46 is, the higher the holding voltage is. Additionally, the decrease of spacing S2 can reduce the current gain of parasitic pnp and npn bipolar transistors of SCR device, thus the holding voltage can be increased. As a result, the shorter the spacing S2 is, the higher the holding voltage is. As shown in FIG. 3, the original holding voltage V_{H1} of the second embodiment is adjusted to V_{H2} larger than power supply V_{DD} after increasing the number of the deep isolation trench 46 or decreasing the spacing S2. In other words, the second embodiment has simple design to adjust the holding voltage with a large range, thereby avoiding the latch-up issue.

Below is the introduction of the bi-directional SCR devices.

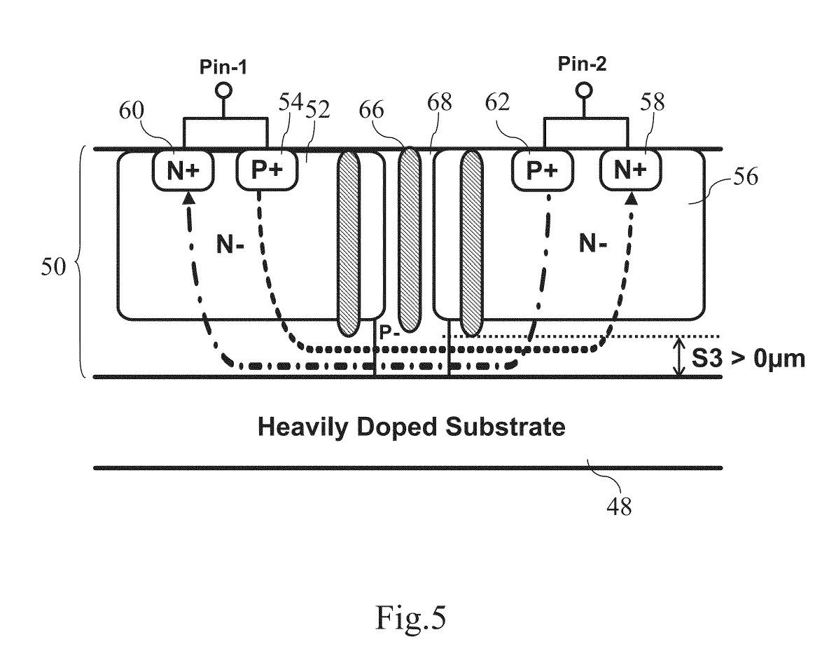

Refer to FIG. 5. The third embodiment of the present invention comprises a heavily doped semiconductor substrate 48 used as a heavily doped semiconductor layer, wherein the heavily doped semiconductor substrate 48 is an N-type heavily doped substrate or a P-type heavily doped substrate. An epitaxial layer 50 is formed on the heavily doped semiconductor substrate 48. A first N-type well 52 is formed in the epitaxial layer 50, and a first P-type heavily doped area 54 is formed in the first N-type well 52. The first N-type well 52 is exemplified by a lightly doped N-type well. A second N-type well 56 is formed in the epitaxial layer 50, and a first N-type heavily doped area 58 is formed in the second N-type well 56. The second N-type well 56 is exemplified by a lightly doped N-type well. A second N-type heavily doped area 60 is formed in the first N-type well 52, and the first P-type heavily doped area 54 and the second N-type heavily doped area 60 are coupled to the first pin. A second P-type heavily doped area 62 is formed in the second N-type well 56, and the first N-type heavily doped area 58 and the second P-type heavily doped area 62 are coupled to the second pin.

At least one deep isolation trench 66 is formed in the epitaxial layer 50. The deep isolation trench 66 is not only located between the first P-type heavily doped area 54 and the first N-type heavily doped area 58 but located between the second N-type heavily doped area 60 and the second P-type heavily doped area 62. The depth of the deep isolation trench 66 is greater than the depths of the first N-type well 52 and the second N-type well 56. There is the spacing S3 defined as a distance between the deep isolation trench 66 and the heavily doped semiconductor substrate 48, wherein the spacing S3 is larger than zero. In addition, the spacing S3 is less than the distance between the heavily doped semiconductor substrate 48 and the first N-type well 52. The spacing S3 is less than the distance between the heavily doped semiconductor substrate 48 and the second N-type well 56. In order to form the SCR structure, a P-type doped area 68 is located between the first N-type well 52 and the second N-type well 56. In the third embodiment, the P-type doped area 68 is exemplified by a lightly doped P-type area. Additionally, the P-type doped area 68 is realized with a second P-type well formed in the epitaxial layer 50. Alternatively, when the epitaxial layer 50 is a P-type epitaxial layer, a part of the P-type epitaxial layer is also used as the P-type doped area 68.

When the first P-type heavily doped area 54 receives the positive ESD pulse while the first N-type heavily doped area 58 is grounded, the ESD current flows from the first P-type heavily doped area 54 to the first N-type heavily doped area 58 through the first N-type well 52, the P-type doped area 68 and the second N-type well 56. When the second P-type heavily doped area 62 receives the positive ESD pulse while the second N-type heavily doped area 60 is grounded, the ESD current flows from the second P-type heavily doped area 62 to the second N-type heavily doped area 60 through the second N-type well 56, the P-type doped area 68 and the first N-type well 52. The deep isolation trench 66 can reduce the current gain of parasitic pnp and npn bipolar transistors of SCR device, thus the holding voltage can be increased. As a result, the more the number of the deep isolation trench 66 is, the higher the holding voltage is. Additionally, the decrease of spacing S3 can reduce the current gain of parasitic pnp and npn bipolar transistors of SCR device, thus the holding voltage can be increased. As a result, the shorter the spacing S3 is, the higher the holding voltage is. As shown in FIG. 3, the original holding voltage V_{H1} of the third embodiment is adjusted to V_{H2} larger than power supply V_{DD} after increasing the number of the deep isolation trench 66 or decreasing the spacing S3. In other words, the third embodiment has simple design to adjust the holding voltage with a large range, thereby avoiding the latch-up issue.

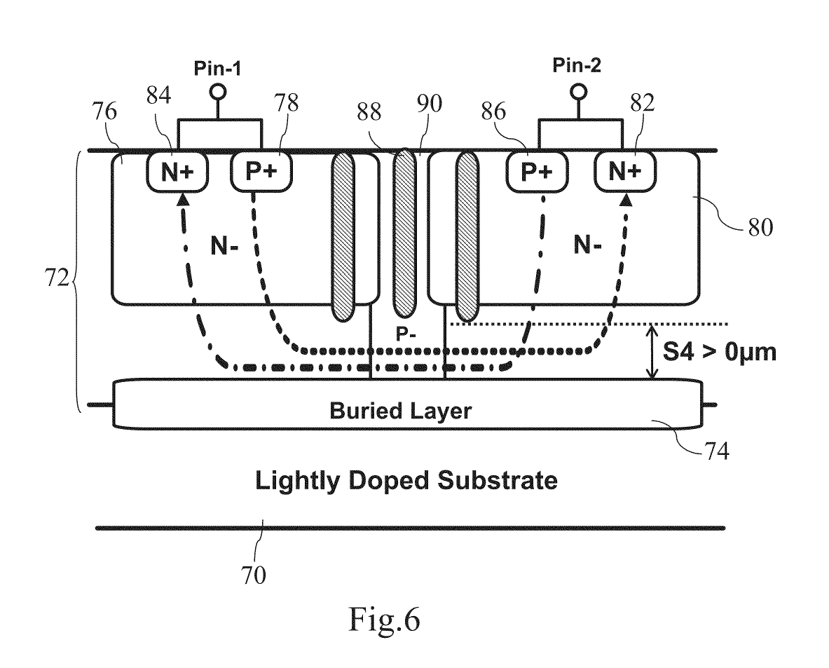

Refer to FIG. 6. The fourth embodiment of the present invention comprises a lightly doped semiconductor substrate 70, such as an N-type lightly doped substrate or a P-type lightly doped substrate. An epitaxial layer 72 is formed on the lightly doped semiconductor substrate 70. A heavily doped buried layer 74, such as an N-type heavily doped buried layer or a P-type heavily doped buried layer, used as a heavily doped semiconductor layer is formed in the epitaxial layer 72 and the lightly doped semiconductor substrate 70, whereby a part of the epitaxial layer 72 is formed on the heavily doped buried layer 74. A first N-type well 76 is formed in the epitaxial layer 72, and a first P-type heavily doped area 78 is formed in the first N-type well 76. The first N-type well 76 is exemplified by a lightly doped N-type well. A second N-type well 80 is formed in the epitaxial layer 72, and a first N-type heavily doped area 82 is formed in the second N-type well 80. The second N-type well 80 is exemplified by a lightly doped N-type well. The first N-type well 76 and the second N-type well 80 are located above the heavily doped buried layer 74. Besides, a second N-type heavily doped area 84 is formed in the first N-type well 76, and the first P-type heavily doped area 78 and the second N-type heavily doped area 84 are coupled to the first pin. A second P-type heavily doped area 86 is formed in the second N-type well 80, and the first N-type heavily doped area 82 and the second P-type heavily doped area 86 are coupled to the second pin.

At least one deep isolation trench 88 is formed in the epitaxial layer 72. The deep isolation trench 88 is not only located between the first P-type heavily doped area 78 and the first N-type heavily doped area 82 but located between the second N-type heavily doped area 84 and the second P-type heavily doped area 86. The depth of the deep isolation trench 88 is greater than the depths of the first N-type well 76 and the second N-type well 80. There is the spacing S4 defined as a distance between the deep isolation trench 88 and the heavily doped buried layer 74, wherein the spacing S4 is larger than zero. In addition, the spacing S4 is less than the distance between the heavily doped buried layer 74 and the first N-type well 76. The spacing S4 is less than the distance between the heavily doped buried layer 74 and the second N-type well 80. In order to form the SCR structure, a P-type doped area 90 is located between the first N-type well 76 and the second N-type well 80. In the fourth embodiment, the P-type doped area 90 is exemplified by a lightly doped P-type area. Additionally, the P-type doped area 90 is realized with a second P-type well formed in the epitaxial layer 72. Alternatively, when the epitaxial layer 72 is a P-type epitaxial layer, a part of the P-type epitaxial layer is also used as the P-type doped area 90.

When the first P-type heavily doped area 78 receives the positive ESD pulse while the first N-type heavily doped area 82 is grounded, the ESD current flows from the first P-type heavily doped area 78 to the first N-type heavily doped area 82 through the first N-type well 76, the P-type doped area 90 and the second N-type well 80. When the second P-type heavily doped area 86 receives the positive ESD pulse while the second N-type heavily doped area 84 is grounded, the ESD current flows from the second P-type heavily doped area 86 to the second N-type heavily doped area 84 through the second N-type well 80, the P-type doped area 90 and the first N-type well 76. The deep isolation trench 88 can reduce the current gain of parasitic pnp and npn bipolar transistors of SCR device, thus the holding voltage can be increased. As a result, the more the number of the deep isolation trench 88 is, the higher the holding voltage is. Additionally, the decrease of spacing S4 can reduce the current gain of parasitic pnp and npn bipolar transistors of SCR device, thus the holding voltage can be increased. As a result, the shorter the spacing S4 is, the higher the holding voltage is. As shown in FIG. 3, the original holding voltage V_{H1} of the fourth embodiment is adjusted to V_{H2} larger than power supply V_{DD} after increasing the number of the deep isolation trench 88 or decreasing the spacing S4. In other words, the fourth embodiment has simple design to adjust the holding voltage with a large range, thereby avoiding the latch-up issue.

In conclusion, the present invention can adjust the number or depth of the deep isolation trench to avoid the latch-up issue.

The embodiments described above are only to exemplify the present invention but not to limit the scope of the present invention. Therefore, any equivalent modification or variation according to the shapes, structures, features, or spirit disclosed by the present invention is to be also included within the scope of the present invention.

What is claimed is:

1. A silicon-controlled-rectifier (SCR) with adjustable holding voltage, comprising:
a heavily doped semiconductor layer;
an epitaxial layer formed on said heavily doped semiconductor layer;
a first N-type well formed in said epitaxial layer;
a first P-type heavily doped area formed in said first N-type well;
a first P-type well formed in said epitaxial layer;
a first N-type heavily doped area formed in said first P-type well; and
at least one deep isolation trench formed in said epitaxial layer and located between said first P-type heavily doped area and said first N-type heavily doped area, wherein a spacing is defined as a distance between said deep isolation trench and said heavily doped semiconductor layer, and wherein said spacing is larger than zero, and a depth of said deep isolation trench is greater than a depth of said first N-type well.

2. The SCR with adjustable holding voltage according to claim 1, wherein said heavily doped semiconductor layer is a heavily doped semiconductor substrate.

3. The SCR with adjustable holding voltage according to claim 2, wherein said heavily doped semiconductor substrate is an N-type heavily doped substrate or a P-type heavily doped substrate.

4. The SCR with adjustable holding voltage according to claim 1, further comprising:
a second N-type heavily doped area formed in said first N-type well; and
a second P-type heavily doped area formed in said first P-type well.

5. The SCR with adjustable holding voltage according to claim 4, wherein said first P-type heavily doped area and said second N-type heavily doped area are coupled to a first pin, and said first N-type heavily doped area and said second P-type heavily doped area are coupled to a second pin.

6. The SCR with adjustable holding voltage according to claim 1, wherein when said first P-type heavily doped area receives a positive ESD pulse while said first N-type heavily doped area is grounded, an ESD current flows from said first P-type heavily doped area to said first N-type heavily doped area through said first N-type well and said first P-type well.

7. The SCR with adjustable holding voltage according to claim 1, wherein said depth of said deep isolation trench is greater than said depth of said first P-type well.
